(19) United States
(12) Patent Application Publication
(10) Pub. No.: US 2013/0319621 A1
(43) Pub. Date: Dec. 5, 2013

(54) TAPE FEEDER AND PARTS MOUNTING DEVICE

(71) Applicant: Chikara Takata, Yamanashi (JP)

(72) Inventor: Chikara Takata, Yamanashi (JP)

(73) Assignee: PANASONIC CORPORATION, Osaka (JP)

(21) Appl. No.: 13/984,638

(22) PCT Filed: Dec. 2, 2011
(86) PCT No.: PCT/JP2011/006772

§ 371 Date: Aug. 9, 2013

(30) Foreign Application Priority Data
Mar. 16, 2011 (JP) 2011-057505

(51) Int. Cl. H05K 13/02

(52) U.S. Cl. CPC H05K 13/02
USPC 156/750

(57) ABSTRACT

On a guide surface 21e formed on a pressing member 21 for guiding carrier tape 15 while pressing it down from its upper surface side, there is provided a projecting portion 27 which projects downwardly in a given range along a tape feed direction correspondingly to such outer edge position of base tape 15a as exists downstream of a tape peeling position peeling off a top tape from the base tape 15a and more outwardly than the feed hole 15d of the base tape 15a. Thus, while the pressing member 21 is pressing down the carrier tape 15 from its upper surface side, the projecting portion 27 is contacted with the outer edge position of the base tape 15a from its upper surface side to thereby prevent the base tape 15a against vibration.

### TECHNICAL FIELD

The present invention relates to a tape feeder for supplying electronic parts held in carrier tape to a pickup position where they are picked up by a parts mounting mechanism, and a parts mounting device incorporating such tape feeder therein.

### BACKGROUND ART

As an electronic part supply device for use in a parts mounting device, there is known a tape feeder. This is a device which intermittently supplies carrier tape holding electronic parts to a pickup position where they are picked up by a mounting head included in a parts mounting mechanism. In the vicinity of the pickup position, the carrier tape is pitch fed along a tape traveling passage formed within the main body of the tape feeder by a tape feed mechanism with the top portion of the carrier tape sealed by top tape. And, the carrier tape, in the vicinity of the pickup position, is held down by a pressing member having a guide surface for guiding the upper surface of the carrier tape. The carrier tape, after the top tape is peeled by a tape peeling mechanism, is picked up by the mounting head of the parts mounting mechanism through an opening formed in the pressing member for taking out parts (for example, see the patent reference 1). In the conventional art technology disclosed in this patent reference, there is illustrated an example in which the carrier tape is held temporarily at a position upstream of a sprocket in the tape traveling passage to thereby maintain the engagement between the carrier tape and sprocket.

### PRIOR ART REFERENCE

### Patent Reference

Patent Reference 1: Japanese Patent Publication 2009-170833

### Disclosure of the Present Invention

### Problems that the Present Invention is to Solve

However, in the conventional technology including the above-cited patent reference, there have been found the following problems caused by the degree of close contact between the guide surface of the pressing member and carrier tape. That is, since the guide surface of the pressing member, in design, is set to have a size allowing such guide surface to be contacted with the upper surface of the top tape, the guide surface does not adhere to the carrier tape perfectly after the top tape is peeled off therefrom but produces a clearance corresponding to the thickness of the top tape; and thus, the carrier tape is fed with such clearance. And, since a portion having such clearance exists in a range where the feed pin of the sprocket is engaged with a feed hole formed in the carrier tape, in the pitch feeding operation of the tape, the carrier tape is caused to vibrate by external force such as friction caused when the feed pin is disengaged from the feed pin.

Such vibration is transmitted to the upstream side of the carrier tape to disturb the attitudes of electronic parts within part pockets. And, when the sizes of the part pockets are small with the reduced sizes of the parts, the influence of such vibration on the attitudes of the parts is large and, in the worst case, there is a fear that such vibration causes the parts to move irregularly and drop out from their part pockets. Thus, in the conventional tape feeder, there is a problem that the vibration caused by the clearance between the pressing member and carrier tape makes the attitudes of the parts unstable to thereby disturb the proper supply of the parts.

Thus, it is an object of the present invention to provide a tape feeder capable of preventing a carrier tape against vibration to thereby stabilize the attitudes of parts and thus secure proper part supply, and a parts mounting device incorporating such tape feeder therein.

### Means for Solving the Problems

### Effects of the Present Invention

According to the present invention, on a guide surface formed on a pressing member for guiding carrier tape while pressing it down from its upper surface side, correspondingly to such outer edge position of base tape as exists at a downstream side of a tape peeling position peeling off the top tape from the base tape and more outwardly than the feed hole of the base tape, there is provided a projecting portion which projects downward in a given range along a tape feed direction. Thus, while the pressing member is pressing down the carrier tape from its upper surface side, the projecting portion is contacted with the outer edge position of the base tape from its upper surface side to thereby prevent the base tape against vibration. This can prevent the carrier tape against vibration and stabilize the part attitude, thereby being able to secure proper part supply.

### BRIEF DESCRIPTION OF THE DRAWINGS

FIG. 1 is a plan view of a parts mounting device according to an embodiment of the present invention.

FIG. 2 is a partial section view of the parts mounting device according to the embodiment of the present invention.

FIG. 3 is an explanatory structure view of a tape feeder according to an embodiment of the present invention.

FIG. 4 is views in which (a) and (b) are respectively explanatory views of the operations of a pressing member mounted to the tape feeder according to the embodiment of the present invention.

FIG. 5 is view in which (a) and (b) are respectively explanatory views of the shape of the pressing member mounted to the tape feeder according to the embodiment of the present invention.

FIG. 6 is an explanatory view of the detailed shape of the pressing member mounted to the tape feeder according to the embodiment of the present invention.

FIG. 7 is view in which (a) and (b) are respectively explanatory views of the function of the pressing member mounted on the tape feeder according to the embodiment of the present invention.

### MODE FOR CARRYING OUT THE PRESENT INVENTION

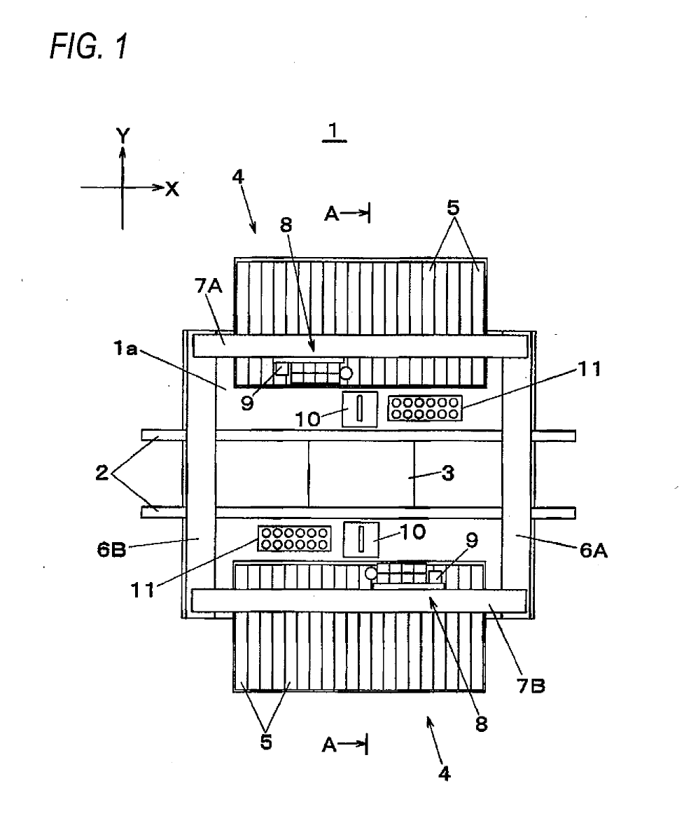

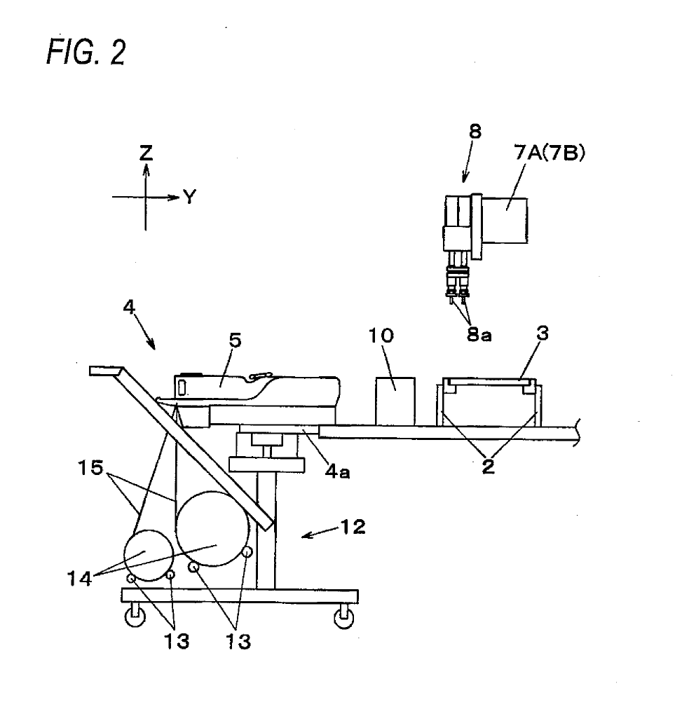

Next, description is given of an embodiment according to the present invention with reference to the accompanying drawings. Firstly, description is given of the structure of a parts mounting device 1 for mounting electronic parts onto a substrate with reference to FIGS. 1 and 2. The parts mounting device 1 has a function to mount electronic parts such as a semiconductor chip onto the substrate, while FIG. 2 shows the AA section in FIG. 1 partially.

In FIG. 1, centrally of a base 1a, there is disposed a substrate delivery mechanism 2 extending in the X direction (in the substrate delivery direction). The substrate delivery mechanism 2 delivers a substrate 3 carried in from the upstream side, and positions and holds it on a mounting stage set for execution of a parts mounting operation. The substrate delivery mechanism 2 serves as a substrate holding portion which positions and holds the substrate 3. On both sides of the substrate delivery mechanism 2, there are provided two part supply portions 4 in each of which multiple tape feeders 5 are arranged side by side. Each tape feeder 5 pitch-feeds carrier tape holding electronic parts thereon to thereby feed the electronic parts to a pickup position where they are picked up by a mounting head included in a parts mounting mechanism to be described below.

On the two end portions of the upper surface of the base 1a, there are provided Y-axis tables 6A and 6B and, on the Y-axis tables 6A and 6B, there are provided two X-axis tables 7A and 7B. By driving the Y-axis table 6A, the X-axis table 7A is moved horizontally in the Y direction; and, by driving the Y-axis table 6B, the X-axis table 7B is moved horizontally in the Y direction. On the X-axis tables 7A and 7B, there are mounted mounting heads 8 and substrate recognition cameras 9 moving integrally with their associated mounting heads 8, respectively.

When the Y-axis table 6A, X-axis table 7A, Y-axis table 6B and X-axis table 7B are driven in combination, the mounting heads 8 are moved horizontally to pick up electronic parts from their respective part supply portions 4 using suction nozzles 8a (see FIG. 2) and mount the parts onto a substrate 3 positioned by the substrate delivery mechanism 2. The Y-axis table 6A, X-axis table 7A, Y-axis table 6B and X-axis table 7B constitute a head moving mechanism for moving the mounting heads 8.

The substrate recognition camera 9, which has moved onto the substrate 3 together with the mounting head 8, takes a picture of the substrate 3 and recognizes it. In a route from the part supply portion 4 to the substrate delivery mechanism 2, there is provided a part recognition camera 10. When the mounting heads 8 having taken out the electronic parts from the part supply portion 4 moves to the substrate 3 positioned on the mounting stage, by moving the electronic parts held by the suction nozzles 8a in the X direction above the part recognition camera 10, the part recognition cameras 10 take pictures of the electronic parts held by the suction nozzles 8a. And, by recognition processing the picture-taken results using a recognition device (not shown), the positions of the electronic parts held by the suction nozzles 8a are recognized and the kinds of the electronic parts are distinguished. A nozzle hold portion 11 stores multiple kinds of suction nozzles 8a at a given attitude and the mounting head 8 accesses the nozzle hold portion 11 to carry out a nozzle replacing operation, whereby nozzle replacement is carried out according to the kinds of the electronic parts to be mounted by the mounting head 8.

Now, description is given of the structure of the part supply portion 4. As shown in FIG. 2, in the part supply portion 4, there is provided a feeder base 4a for mounting multiple tape feeders 5 thereon. The tape feeders 5 are arranged in the part supply portion 4 by a feeder mounting cart 12, while the cart 12 includes reel hold portions 13 for holding a tape reel 14 with carrier tape 15 wound thereon. The reel hold portion 13 includes a hold roller for holding the tape reel 14 rotatably and thus, by rotating the tape reel 14 arranged in the part supply portion 4, the carrier tape 15 can be pulled out.

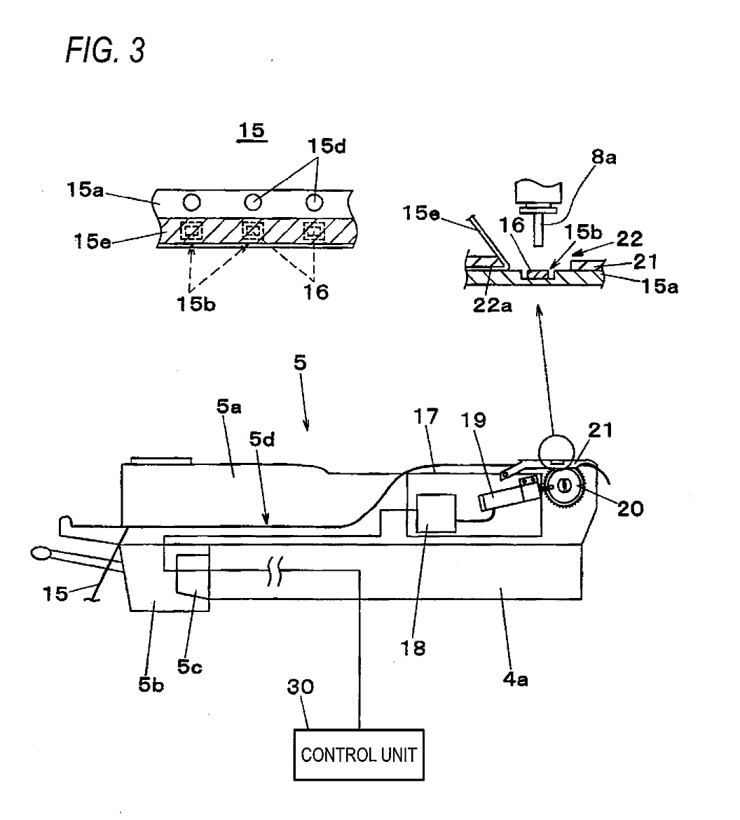

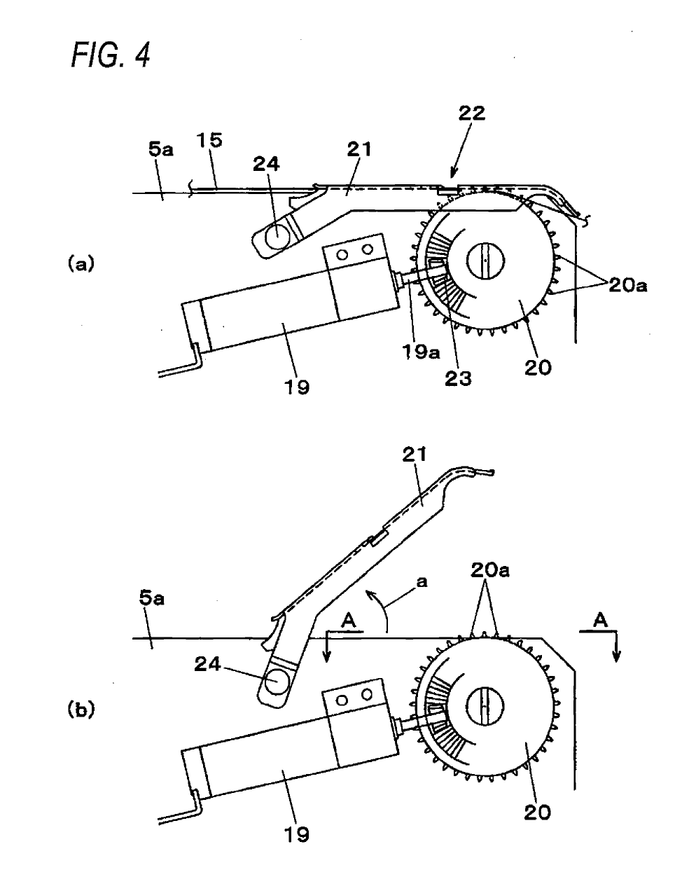

Next, description is given of the structure and function of the tape feeder 5 with reference to FIGS. 3 and (a) and (4) in FIG. 4. As shown in FIG. 3, the tape feeder 5 includes a main body portion 5a and a mounting portion 5b provided on and projected downward from the lower surface of the main body portion 5a. In a state where the tape feeder 5 is mounted with the lower surface of the main body portion 5a applied along the feeder base 4a, a connector section 5c formed in the mounting portion 5b is engaged with the feeder base 4a. Thus, the tape feeder 5 is fixed and mounted to the part supply portion 4 and is also electrically connected to the control unit 30 of the parts mounting device 1.

Within the main body portion 5a, a tape traveling passage 5d, which is used to guide the carrier tape 15 pulled out from the tape reel 14 and taken into the main body portion 5a, is formed to extend continuously from the rear end portion of the main body portion 5a to the leading end portion thereof. The carrier tape 15 is constituted of paper-made base tape 15a constituting a tape main body, part pockets 15b or part storing recesses for storing and holding the electronic parts 16 therein, and feed holes 15d formed at given pitches for pitch feeding the carrier tape 15. The upper surface of the base tape 15a covers the part pockets 15b and is sealed by top tape 15e in order to prevent the electronic parts 16 from slipping out of the part pockets 15b.

The main body portion 5a incorporates therein a tape feed section 17 for pitch feeding the carrier tape 15. The tape feed section 17 includes a feed motor 19 for rotationally driving a sprocket 20 provided on the leading end portion of the tape traveling passage 5d and a feeder control section 18 for controlling the feed motor 19. In a state where the tape feeder 5 is mounted to the feeder base 4a, the feeder control section 18 is connected to the control unit 30.

As shown in (a) and (b) in FIG. 4, on the sprocket 20, there are provided feed pins 20a at given pitches which can be engaged with the feed holes 15d. With the feed pins 20a engaged into the feed holes 15d, when the feed motor 19 is driven to intermittently rotate the sprocket 20 through a bevel gear 23 connected to the rotation shaft 19a, the carrier tape 15 is pitch fed downstream (in FIG. 3, (a) and (b) in FIG. 4, to the right side). The sprocket 20 and feed motor 19 constitute a tape feed mechanism which is provided in the main body portion 5a and intermittently rotates the sprocket 20 with the feed pins 20a of the sprocket 20 engaged into the feed holes 15d to thereby pitch feed the carrier tape 15 at given pitches.

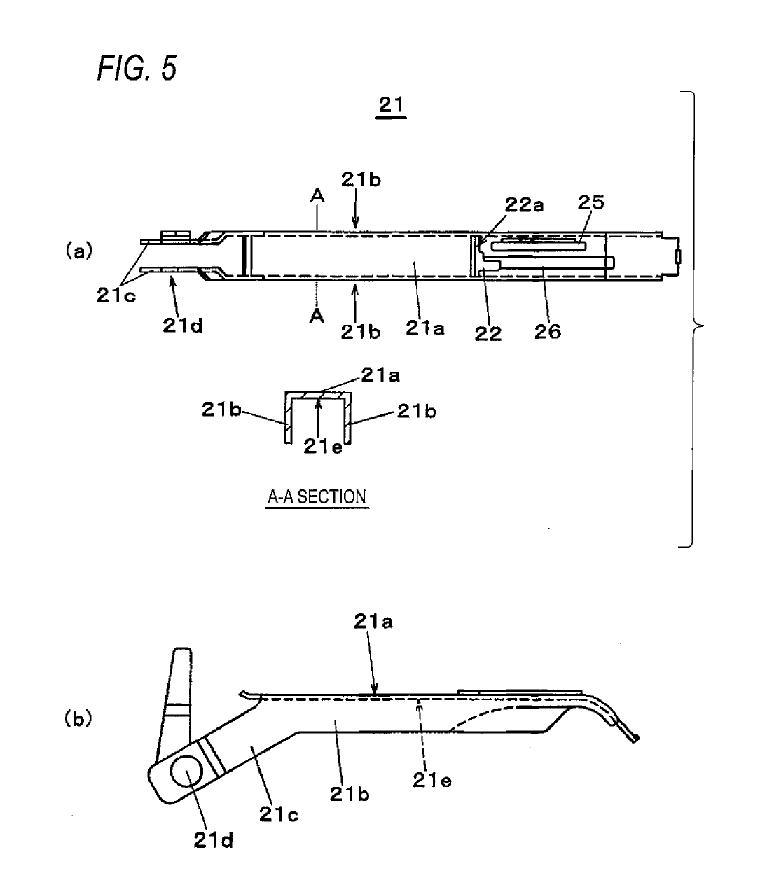

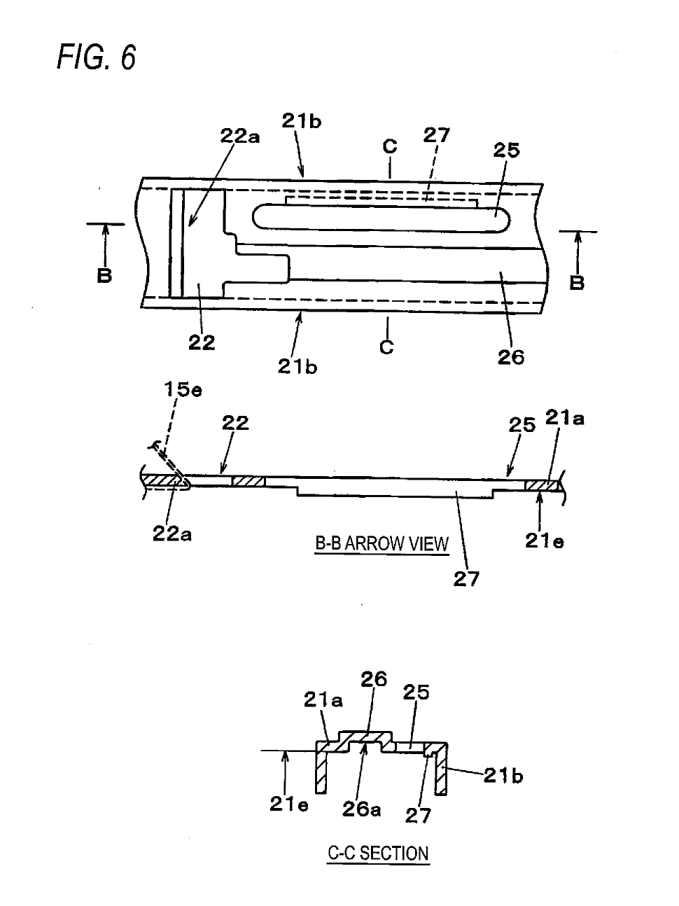

This side of the sprocket 20 provides a pickup position where the electronic parts 16 within the part pockets 15b are sucked by the suction nozzles 8a of the mounting heads 8 and are taken out from the part pockets. The main body portion 5a includes, on its upper surface side existing near the sprocket 20, a pressing member 21 which can be rotated with a pivot pin 24 as its pivot point. In a state shown in (a) in FIG. 4, the pressing member 21, in a given range including the pickup position of the tape traveling passage 5d, guides the carrier tape 15 while pressing it down from its upper surface side using a guide surface 21e (see FIGS. 5 and 6).

This given range is set for a range necessary to guide the carrier tape 15 to the pickup position using the suction nozzles 8a and also to properly engage the feed holes 15d with the feed pins 20a. Also, as shown in (b) in FIG. 4, in a state where the pressing member 21 is rotated in the arrow a direction with the pivot pin 24 as its pivot point, the top surface of the sprocket 20 is opened in the tape traveling passage 5d. This enables an operator to carry out a tape mounting operation to engage the feed holes 15d with the feed pins 20a by operating the carrier tape 15.

The pressing member 21 includes a suction opening 22 formed to correspond to the pickup position by the suction nozzle 8a. The upstream end of the suction opening 22 provides a top tape peeling section 22a for peeling off the top tape 15e (see also (a) and (b) in FIG. 5). That is, while the carrier tape 15 is traveling below the pressing member 21, by moving the top tape 15e around the top tape peeling section 22a and pulling it out to the upstream side, the top tape 15e is peeled off the substrate 15a at a tape peeling position (the position of the top tape peeling section 22a) existing upstream of the pickup position and is turned back to the upstream side. The turned-back top tape 15e is fed by a top tape feed mechanism (not shown) into a tape collection section formed within the main body portion 5a and is collected. This allows the electronic parts 16 within the part pockets 15b to be exposed upwardly of the suction opening 22, whereby they can be taken out by the suction nozzle 8a. The top tape peeling section 22a and top tape feed mechanism formed in the suction opening 22 constitute a peeling mechanism which peels off the top tape 15e from the base tape 15a at a tape peeling position set at an upstream side of the pickup position in the tape feed direction.

Now, description is given of the specific shape of the pressing member 21 with reference to (a) and (b) in FIG. 5 and FIG. 6. FIG. 6 shows the specific shape of the vicinity of the suction opening 22 in the pressing member 21. As shown in the A-A section in (a) in FIG. 5, the pressing member 21 is constituted mainly of a rectangular member having a downwardly-opened rectangular frame-like section shape, that is, a section shape having two side surface portions 21b extended downwardly from the two sides of a horizontal upper surface 21a. The back surface of the upper surface portion 21a provides a guide surface 21e for guiding the upper surface of the carrier tape 15 while pressing it down from above.

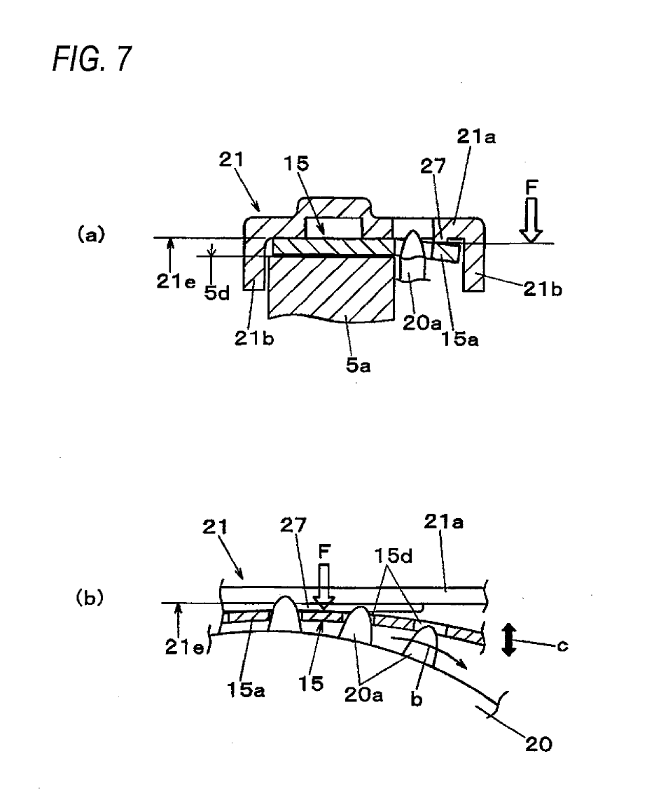

As shown in (b) in FIG. 5, the leading end portion of the pressing member 21 on its upstream side (in (a) and (b) in FIG. 5, on the left side) provides a pivot portion 21c having the two side surface portions 21b extended downwardly. When a pivot hole 21d formed in the pivot portion 21c is pivotally supported by a pivot pin 24, the pressing member 21 is connected to the main body portion 5a in such a manner that it can be opened and closed. When the pressing member 21 is closed with respect to the main body portion 5a, that is, in a state where the pressing member 21 is rotated around the pivot pin 24 to cover the main body portion 5a from above, the side surface portions 21b of the pressing member 21 are situated on the side surfaces of the main body portion 5a and guide the width direction of the carrier tape 15. Also, in this state, the guide surface 21e formed on the back surface of the upper surface portion 21a is situated on the upper surface of the carrier tape 15 being fed along the tape traveling passage 5d and guides this upper surface while pressing down the carrier tape 15 from above (see (a) in FIG. 7).

As shown in FIG. 6, downstream of the suction opening 22, in order to avoid the interference of the sprocket 20 with the feed pin 20a in the mounted state shown in (a) in FIG. 4, there is formed a pin escape opening 25 formed for pin escape at a position corresponding to the position of the sprocket 20 in the main body portion 5a. On the downstream side of the suction opening 22 in the upper surface portion 21a, as shown in the C-C section, correspondingly to the position of the part pocket 15b in the carrier tape 15, there is formed an upwardly projecting projection-worked section 26 parallel to the pin escape opening 25. And, such range of the guide surface 21e as corresponds to the projection-worked section 26 provides a recessed section 26a.

The recessed section 26a functions as a space used to discharge to the downstream side the electronic part 16 which is not picked up properly in a part pickup operation by the suction nozzle 8a but is left within the suction opening 22. This can prevent abnormal tape feed caused when the electronic part 16 left in pickup error is inserted between the pressing member 21 and suction nozzle 8a.

On such edge of the guide surface 21e as exists outside the pin escape opening 25, there is provided a projecting portion 27 which projects downward with a given projection margin (for example, 0.1-0.3 mm) and extends more than half the total length of the pin escape opening 25 along the longitudinal direction of the pin escape opening 25 (in the tape feed direction). The position of the projecting portion 27 in the tape width direction is set at a position where, in a state where the pressing member 21 is closed with respect to the main body portion 5a and presses down the carrier tape 15 from its upper surface side, the projecting portion 27 is contacted with such outer edge position of the base tape 15a as exists outwardly of the feed hole 15d.

In a state where, after the carrier tape 15 is mounted to the main body portion 5a, the pressing member 21 is closed to press down the carrier tape 15 from above, as shown in (a) in FIG. 7, the projecting portion 27 is contacted with such outer edge position of the base tape 15a as exists outwardly of the feed hole 15d engaged with the feed pin 20a, thereby pressing the base tape 15a downward by an amount corresponding to its projection margin. Thus, force F corresponding to flexing external force causing the base tape 15a to flex downward is applied onto the outer edge position of the base tape 15a. This force F can prevent the substrate 15a against vibration in the tape feeding operation by the sprocket 20.

In the conventional technology, the guide surface 21e formed on the pressing member 21, in design, is formed to have a dimension allowing the guide surface 21e to be contacted with the upper surface of the carrier tape 15 including the top tape 15e. In this case, after the top tape 15e is peeled, the guide surface 21e is not perfectly closely contacted with the carrier tape 15, that is, such upper surface of the base tape 15a as exists downstream of the tape peeling position, but the tape is fed with a slight clearance corresponding to the thickness of the top tape 15e. Therefore, in the range where such clearance is produced, when there are generated vibrations for some reason, for example, when there are generated vibrations due to external force such as friction produced when the feed pin 20a is disengaged from the feed hole 15d, such vibrations spread to the upstream side of the carrier tape 15 to make unstable the attitudes of the electronic parts in the part pockets 15b after the top tape 15e is peeled, thereby disturbing the proper supply of the electronic parts.

On the other hand, in this embodiment, the projecting portion 27 is provided to extend substantially more than half the whole length of the pin escape opening 25. In this case, in the range where the feed pin 20a is engaged with the feed hole 15d, onto the outer edge position of the base tape 15a, as shown in (b) in FIG. 7, there is applied the force F that is generated due to contact of the projecting portion 27 with the upper surface of the base tape 15a. This force F acts on the base tape 15a as vibration preventive external force, whereby vibrations (arrow c) induced in the base tape 15a due to external force such as friction generated when the feed pin 20a is disengaged from the feed hole 15d by the intermittent rotation (arrow b) of the sprocket 20 in the tape pitch feeding operation can be prevented from spreading to the upstream side. This can eliminate the inconvenience that the part attitude is made unstable due to the vibrations of the base tape 15a in the part pockets 15b after the top tape 15e is peeled.

In the above embodiment, there is illustrated an example in which the projecting portion 27 is provided on the outer edge of the pin escape opening 25. However, the position and range of the projecting portion 27 can also be set properly in the other position and range. That is, so long as they exist downstream in the tape feeding direction of the tape peeling position to be specified by the top tape peeling section 22a and they are such outer edge positions of the base tape 15a as exist more outwardly than the feed hole 15d, the range where the projecting portion 27 is contacted with the outer edge position of the base tape 15a from its upper surface side and thus can secure the base tape 15a vibration preventive effect sufficiently, may be decided by trying a conditioning operation or the like.

As described above, in this embodiment, on the guide surface 21e formed on the pressing member 21 for guiding the carrier tape 15 while pressing it down from its upper surface side, correspondingly to the outer edge position of the base tape 15a which exists downstream in the tape feed direction of the tape peeling position to be specified by the top tape peeling section 22a of the suction opening 22 and more outwardly than the feed hole 15d in the base tape 15a, there is provided the projecting portion 27 projecting downward in a given range along the tape feed direction. Thus, in a state where the pressing member 21 presses down the carrier tape 15 from its upper surface side, the projecting portion 27 is contacted with the outer edge position of the base tape 15a to prevent the base tape 15a against vibration and thus prevent the carrier tape 15 against vibration, thereby being able to stabilize the part attitude and secure the proper part supply.

Here, the present invention also implies that a person skilled in the art can provide various changes and applications according to the description of the specification and well-known technology without departing from the gist and scope of the present invention, and such changes and applications also come within the scope of the claim. Also, the respective composing elements of the above embodiment may also be combined arbitrarily without departing from the subject matter of the present invention.

This application is based on Japanese Patent Application (JPA2011-057505) filed on Mar. 16, 2011 and the contents thereof are incorporated herein for reference.

### INDUSTRIAL APPLICABILITY

The tape feeder of the present invention provides an effect that it prevents a carrier tape against vibration to stabilize the attitude of parts, thereby being able to secure proper part supply. Thus, the present invention is useful in a parts mounting field in which electronic parts are taken out from a tape feeder and are mounted onto a substrate.

### DESCRIPTION OF REFERENCE NUMERALS AND SIGNS

1: Parts mounting device
3: Substrate
4: Part supply portion
5: Tape feeder
5a: Main body portion
5d: Tape traveling passage
8: Mounting head
8a: Suction nozzle
15: Carrier tape
15a: Base tape
15b: Part pocket
15d: Feed hole
15e: Top tape
16: Electronic part
17: Tape feed portion
19: Feed motor
20: Sprocket
20a: Feed pin
21: Pressing member
21e: Guide surface
22: Suction opening
22a: Top tape peeling section
25: Pin escape opening
27: Projecting portion

1. A tape feeder for pitch feeding, in a tape feed direction, a carrier tape including a base tape having an electronic part stored in a recessed portion thereof and having an upper surface sealed by a top tape so as to supply the electronic part to a pickup position where the electronic part is picked up by a mounting head, the tape feeder comprising:
a sprocket including feed pins to be engaged with feed holes formed at given pitches in the base tape;
a tape feed mechanism intermittently rotating the sprocket to pitch feed the carrier tape along a tape traveling passage;
a peeling unit peeling off the top tape from the base tape at a tape peeling position set at an upstream side of the pickup position in the tape feed direction;
a pressing member including a guide surface guiding the carrier tape while pressing down the carrier tape in a given range containing the pickup position of the tape traveling passage; and
a projecting portion provided on the guide surface and projected downwardly in a given range along the tape feed direction, the projecting portion being disposed to correspond to an outer edge position of the base tape existing downstream of the tape peeling position in the tape feed direction and more outwardly than the feed holes of the base tape,
wherein, while the pressing member is pressing down the carrier tape from an upper surface side thereof, the projecting portion is contacted with the outer edge position of the base tape from the upper surface side thereof to prevent the base tape against vibration.

2. The tape feeder according to claim 1, wherein the projecting portion is formed along the edge portion of a pin escape opening formed in the pressing member for escape of the feed pin of the sprocket.

3. The tape feeder according to claim 1, wherein the carrier tape includes a base tape made of paper material.

4. A parts mounting device for taking out an electronic part from a tape feeder and mounting the electronic part onto a substrate by a mounting head, the tape feeder being mounted to a part supply portion and pitch feeding, in a tape feed direction, a carrier tape including a base tape having the electronic part stored in a recessed portion thereof and having an upper surface sealed by a top tape so as to supply the electronic part to a pickup position where the electronic part is picked up by the mounting head, the parts mounting device comprising:
a substrate holding portion for positioning and holding the substrate; and
a parts mounting mechanism moving the mounting head between the part supply portion and the base hold portion so as to mount the electronic part onto the substrate,
wherein the tape feeder comprises a sprocket including feed pins to be engaged with feed holes formed at given pitches in the base tape; a tape feed mechanism intermittently rotating the sprocket to pitch feed the carrier tape along a tape traveling passage; a peeling unit peeling off the top tape from the base tape at a tape peeling position set at an upstream side of the pickup position in the tape feed direction; a pressing member including a guide surface for guiding the carrier tape while pressing down the carrier tape in a given range containing the pickup position of the tape traveling passage; and a projecting portion provided on the guide surface and projected downwardly in a given range along the tape feed direction, the projecting portion being disposed to correspond to the outer edge position of the base tape existing downstream of the tape peeling position in the tape feed direction and more outwardly than the feed holes of the base tape,
wherein, while the pressing member is pressing down the carrier tape from the upper surface side thereof, the projecting portion is contacted with the outer edge position of the base tape from the upper surface side thereof to prevent the base tape against vibration.
